(19) United States
(12) Patent Application Publication
(10) Pub. No.: US 2009/0211786 A1
(43) Pub. Date: Aug. 27, 2009

(54) PROCESS FOR PRODUCING POLYIMIDE FILM WITH COPPER WIRING

(76) Inventors: Keita Bamba, Ichihara-shi (JP); Tadahiro Yokozawa, Ichihara-shi (JP); Hiroto Shimokawa, Ube-shi (JP); Nobu Iizumi, Ube-shi (JP)

Correspondence Address: KNOBBE MARTENS OLSON & BEAR LLP, 2040 MAIN STREET, FOURTEENTH FLOOR, IRVINE, CA, 92614, US

(21) Appl. No.: 12/090,251

(22) PCT Filed: Oct. 13, 2006
(86) PCT No.: PCT/JP2006/320500

§ 371 Date: Mar. 19, 2009

(30) Foreign Application Priority Data
Oct. 14, 2005 (JP) 2005-300980

(51) Int. Cl. H05K 1/00; H05K 3/06; H05K 3/26; H01L 21/288

(52) U.S. Cl. 174/250; 29/846; 29/847

(57) ABSTRACT

Is disclosed a process for producing a copper-wiring polyimide film from a carrier-accompanied copper foil laminated polyimide film by a subtractive method or a semi-additive method. Washing the polyimide surface exposed by etching the copper foil with a etching solution capable of removing mainly at least one metal selected from Ni, Cr, Co, Zn, Sn and Mo or an alloy comprising at least one of these metals used for a surface treatment of the copper foil restrains an anomalous deposition of plating substances when the copper wiring is plated with tin.

### TECHNICAL FIELD

The present invention relates to a process for producing a copper-wiring polyimide film with excellent properties of metal-plating such as tin-plating by using a carrier-accompanied copper foil laminated polyimide film by means of a subtractive method or a semi-additive method.

### BACKGROUND ART

Conventionally, carrier-accompanied copper foil laminated polyimide films, in which a carrier-accompanied copper foil is laminated to a polyimide film, have been widely used for high-performance electronic devices, in particular flexible wiring substrates and IC carrier tapes with high-density wirings and suitable for reduction in size and weight because of their excellent properties with thinness and lightness in weight.

Patent document 1 discloses a process for producing a metal-clad laminate by semi-additive method in which a metal foil is located on at least one side of an adhesive film, comprising at least steps of thermally laminating the adhesive film having an adhesive layer comprising a thermoplastic polyimide on at least one side of an insulating film and the metal foil with a de-lamination layer between at least one pair of metal rolls through a protective film so that the metal foil contacts the adhesive layer of the adhesive film; stripping said protective film from the laminate obtained by the heat lamination; and stripping said de-lamination layer from the metal foil.

Patent document 2 discloses a copper-clad laminate comprising a copper foil with 1 to 8 μm in thickness, an adhesive layer containing a thermoplastic polyimide resin as a main component, and a heat-resistant film, and produced by a process comprising the steps of forming the adhesive layer on the heat-resistant film; locating a carrier-accompanied copper foil on a surface of the adhesive layer; applying heat and pressure on a resultant laminate in order for the adhesive layer in the laminate to adhere to the carrier-accompanied copper foil; and delaminating the carrier.

List of Patent document:

Patent document 1: Japanese Laid-open Patent Publication No. 2005-254,632

Patent document 2: Japanese Laid-open Patent Publication No. 2002-316,386

### DISCLOSURE OF THE INVENTION

### Problems to be Solved by the Invention

A copper-wiring polyimide film is manufactured, for example, by using a carrier-accompanied copper foil laminated polyimide film, in which a carrier-accompanied copper foil is laminated to a polyimide film, by means of a subtractive method or a semi-additive method. However, in the case of a copper-wiring polyimide film in which copper fine wirings are formed by etching a copper film through a subtractive method or a semi-additive method using a carrier-accompanied copper foil laminated polyimide film, anomalous deposition of metal-plating substances may occur on a polyimide surface which has emerged by removing a copper foil, after metal plating such as tin plating is carried out on at least a part of copper wirings.

An objective of the present invention is to provide a process for producing a copper-wiring polyimide film that has fine copper wiring formed by etching a copper foil through a subtractive method or a semi-additive method using a carrier-accompanied copper foil laminated polyimide film, and that is improved in electrical insulating properties, restraining anomalous deposition of metal-plating substances after metal plating such as tin plating is carried out on at least a part of copper wirings.

### Means for Solving the Problems

A first aspect of the present invention relates to a process for producing a copper-wiring polyimide film, from a carrier-accompanied copper foil laminated polyimide film, by means of a subtractive method, the process comprising at least steps of:

1) stripping the carrier foil from the carrier-accompanied copper foil laminated polyimide film;
2) optionally plating copper on the copper foil;
3) forming an etching resist layer on an upper face of the copper foil;
4) exposing to light in a wiring pattern;
5) developing and removing the etching resist layer except a portion where the wiring pattern is intended to be formed;
6) removing by etching the copper foil except a portion where the wiring pattern is intended to be formed;
7) removing by stripping the etching resist layer; and
8) washing with an etching solution capable of removing at least one metal selected from Ni, Cr, Co, Zn, Sn and Mo or an alloy comprising at least one of these metals.

A second aspect of the present invention relates to a process for producing a copper-wiring polyimide film, from a carrier-accompanied copper foil laminated polyimide film, by means of a semi-additive method, the process comprising at least steps of:

1) stripping the carrier foil from the carrier-accompanied copper foil laminated polyimide film;
2) optionally thinning by etching the copper foil;
3) forming a plating-resist layer on an upper face of the copper foil;
4) exposing to light in a wiring pattern;
5) developing and removing a portion of the plating-resist layer where the wiring pattern is intended to be formed;
6) plating copper on the bare part of the copper foil;
7) removing by stripping the plating-resist layer on the copper foil;
8) removing by flash-etching a portion of the copper foil where the plating-resist layer is removed to bare the polyimide; and
9) washing with an etching solution capable of removing at least one metal selected from Ni, Cr, Co, Zn, Sn and Mo or an alloy comprising at least one of these metals.

The preferred embodiments according to the present invention are indicated below. A plurality of these embodiments may be combined.

1) In the carrier-accompanied copper foil laminated polyimide film, a surface of the carrier-accompanied copper foil is surface-treated with at least one metal selected from Ni, Cr, Co, Zn, Sn and Mo or an alloy comprising at least one of these metals (hereafter, the metal used for the surface-treatment of the copper foil surface is referred to as surface-treatment metal) and the surface is laminated to the polyimide film.
2) The etching solution is an acidic etching solution.
3) The etching solution is an etching agent for a Ni—Cr alloy (Ni—Cr seed layer remover).
4) In the polyimide film, a thermocompression-bondable polyimide layer is laminated on at least one side of a (high) heat-resistant polyimide layer, and in the carrier-accompanied copper foil laminated polyimide film, the surface-treated face of the copper foil is laminated on the thermocompression-bondable polyimide layer of the polyimide film. Preferably, in the polyimide film, a thermocompression-bondable polyimide layer is laminated on at least one side of a high heat-resistant polyimide layer, and in the carrier-accompanied copper foil laminated polyimide film, the surface-treated face of the copper foil is laminated by heat and pressure on the thermocompression-bondable polyimide layer of the polyimide film.
5) In the copper-wiring polyimide film, copper wirings with not more than 80 μm in pitch are formed on at least one side of the polyamide film.
6) After the washing step, at least a part of said copper-wiring is metal-plated.

Furthermore, another aspect of the present invention relates to the copper-wiring polyimide film produced by the production process described above.

### EFFECT OF THE INVENTION

The copper-wiring polyimide film manufactured in accordance with the present invention is able to prevent or restrain an anomalous deposition of plating metal on the surface of the polyimide film on which the copper foil between copper wirings is removed by etching or on the surface site of the polyimide film adjacent to copper wirings when at least a part of copper wirings is plated with metal such as tin. Therefore, electrical insulating properties and appearances of substrate resultant after etching are improved.

The copper-wiring polyimide film manufactured in accordance with the present invention is able to form fine wirings with 40 μm in pitch or less and 50 μm in pitch or less by etching a copper film, and high-density flexible wiring substrates, build-up circuit substrates and IC carrier tapes with wirings are able to be obtained.

### BRIEF DESCRIPTION OF THE DRAWINGS

FIG. 1 is a process chart illustrating an example of the process for production of the copper-wiring polyimide film by using the carrier-accompanied copper foil laminated polyimide film by means of the subtractive method.

FIG. 2 is a process chart illustrating an example of the process for production of the copper-wiring polyimide film by using the carrier-accompanied copper foil laminated polyimide film by means of the semi-additive method.

FIG. 3 is an image, obtained by a metallographic microscope, of the surface of the tin-plated copper-wiring polyimide film in the example 1 according the present invention.

FIG. 4 is an image, obtained by a metallographic microscope, of the surface of the tin-plated copper-wiring polyimide film in the comparative example 1 according the present invention.

### EXPLANATION OF THE REFERENCES

1: Carrier-accompanied copper foil laminated polyimide film
2: Polyimide film
3: Carrier-accompanied copper foil
4: Copper foil
5: Carrier
6, 10: Copper plating
7, 17: Photoresist layer
8: Polyimide film surface emerged after removing copper foil
9: Metal plating
21: Tin-plated copper wiring
22: Polyimide film surface by removing copper foil
23: Anomalous deposition site of tin-plating
24: Boundary between tin-plated copper wiring and polyimide film surface by removing copper foil

### BEST MODE FOR CARRYING OUT THE INVENTION

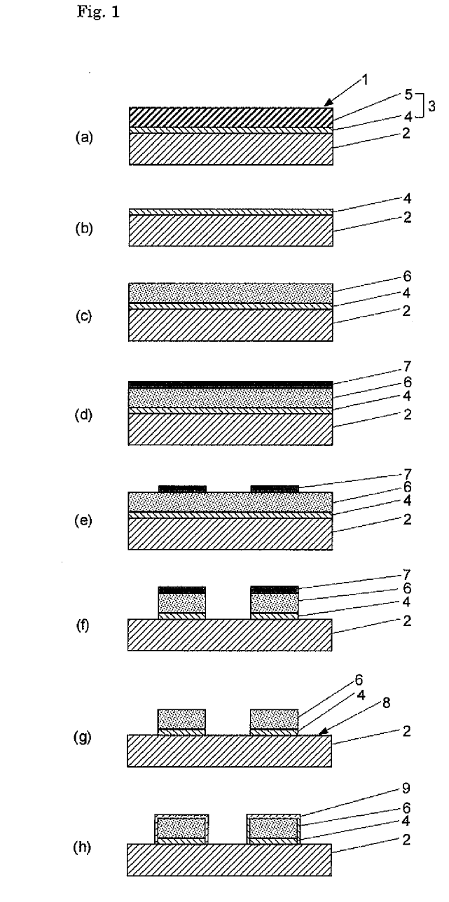

FIG. 1 shows an embodiment for the process of producing the copper wiring polyimide film by the subtractive method using the carrier-accompanied copper foil laminated polyimide film, and furthermore the production process of the plated copper wiring polyimide film in the order of the step (a) to the step (h).

At the step (a), as shown in FIG. 1(a), the carrier-accompanied copper foil laminated polyimide film 1 to be used for producing the copper wiring polyimide film according to the present invention is provided. The carrier-accompanied copper foil laminated polyimide film 1 has the laminate structure of the polyimide film 2 and the carrier-accompanied copper foil 3. The carrier-accompanied copper foil 3 has the laminate structure of the copper foil 4 and the carrier foil 5.

At the step (b), as shown in FIG. 1(b), the carrier foil 5 is stripped from the carrier-accompanied copper foil laminated polyimide film 1, and then at the step (c), as shown in FIG. 1(c), the upper part of the copper foil of the copper foil laminated polyimide film is copper-plated 6. At the step (d), as shown in FIG. 1(d), the photoresist layer 7 is formed on the upper part of the copper-plated layer 6 of the copper foil laminated polyimide film. At the step (e), as shown in FIG. 1(e), the photoresist layer is exposed to light using the mask of a wiring pattern, and is developed and removed except the portion to be the wiring pattern. Then, the copper-plated layer other than the portion of the wiring pattern site is bared.

At the step (f), as shown in FIG. 1(f), the copper-plated layer emerging by developing and removing the photoresist layer 7 and a copper foil (this part is the portion that does not become the wiring pattern) is removed by etching. Then at the step (g), as shown in FIG. 1(g), the photoresist layer 7 on the upper part of the copper-plated layer is removed, and the polyimide film surface 8, where the copper foil has been removed, is washed with the etching solution capable of removing mainly at least one metal selected from Ni, Cr, Co, Zn, Sn and Mo or an alloy comprising at least one of these metals.

Furthermore at the step (h), as shown in FIG. 1(h), the plated copper-wiring polyimide film is produced by tin-plating on at least a part of the copper wiring of the copper-wiring polyimide film and forming the tin-plated layer 9.

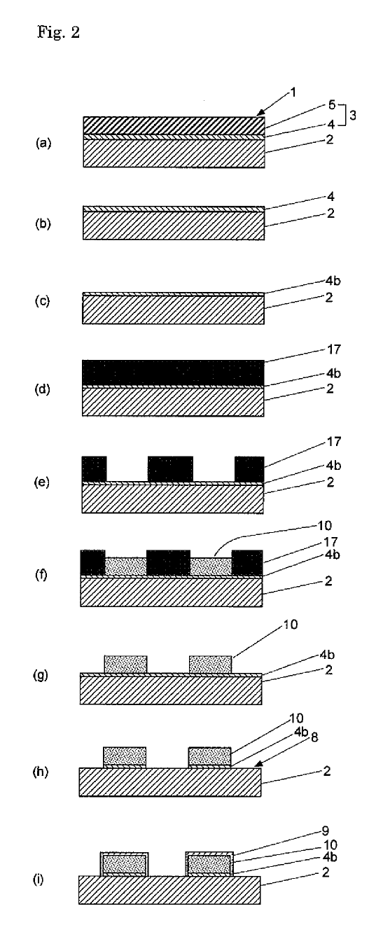

FIG. 2 shows an embodiment for the process of producing the copper wiring polyimide film by the semi-additive method using the carrier-accompanied copper foil laminated polyimide film, and furthermore the production process of the plated copper wiring polyimide film in the order of the step (a) to the step (i).

At the step (a), as shown in FIG. 2(a), the carrier-accompanied copper foil laminated polyimide film 1 to be used for producing the copper wiring polyimide film according to the present invention is provided. The carrier-accompanied copper foil laminated polyimide film 1 has the laminate structure of the polyimide film 2 and the carrier-accompanied copper foil 3. The carrier-accompanied copper foil 3 has the laminate structure of the copper foil 4 and the carrier foil 5.

At the step (b), as shown in FIG. 2(b), the carrier foil 5 is stripped from the carrier-accompanied copper foil laminated polyimide film 1, and then at the step (c), as shown in FIG. 2(c), etching is carried out to make thinner the copper foil of the copper foil laminated polyimide (half etching). Then at the step (d), as shown in FIG. 2(d), the photoresist layer 17 is formed on the upper part of the copper foil of the copper foil laminated polyimide film, and at the step (e), as shown in FIG. 2(e), the photoresist layer is exposed to light using the mask of a wiring pattern, and the portion of the photoresist where the wiring pattern is formed is developed and removed, and the copper foil to be the wiring pattern site is bared.

Then at the step (f), as shown in FIG. 2(f), the copper-plated layer 10 is formed on the upper part of the copper foil to be the wiring pattern emerged after removing the photoresist layer 17. At the step (g), as shown in FIG. 2(g), the photoresist layer 17 remaining on the copper foil is removed.

Then at the step (h), as shown in FIG. 2(h), the site of the copper foil not to be the wiring pattern is removed by flash-etching. Subsequently, the bare polyimide film surface 8 after removing the copper foil is washed with the etching solution capable of removing mainly at least one metal selected from Ni, Cr, Co, Zn, Sn and Mo or an alloy comprising at least one of these metals.

Furthermore at the step (i), as shown in FIG. 2(i), the plated copper-wiring polyimide film is produced by tin-plating on at least a part of the copper wiring of the copper-wiring polyimide film and forming the tin-plated layer 9.

In each step of the subtractive and semi-additive method above, the copper-plating step of FIG. 1(c) may be carried out if needed, and for example, the copper-plating step is preferably done when the copper foil is thin. In addition, the film-thinning step of the copper foil in FIG. 2(c) may be carried out if needed, and for example, the film-thinning step of the copper foil is preferably done when the copper foil is thick. Determining whether the copper foil is thick or thin may depend on its purpose of use.

In FIG. 1(d) and FIG. 2(d), the photoresist layer may be a negative type and a positive type and may be a liquid form and a film form. Typical, the photoresist is formed on copper foil by heat laminating the negative dry film-type resist, or applying and drying the liquid-type resist. In the case of the negative-type, an unexposed site is removed; alternatively in the case of the positive-type, an exposed site is removed by developing. The thicker resist may be easily obtained using dry film-type resist. For example, SPG-152 made by Asahi Chemical Industry and RY-3215 made by Hitachi Kasei is exemplified as the negative dry film-type photoresist.

For the method to develop and remove the photoresist layer in FIG. 1(e) and FIG. 2(e), known chemical(s) for developing and removing a photoresist layer may be appropriately selected. For example, a photoresist layer may be developed and removed by spraying sodium carbonate aqueous solution (1% etc) and so on.

For the copper-plating step in FIG. 1(c) and FIG. 2(f), a known plating condition may be appropriately selected. For example, the copper layer is formed by washing an bare site of copper foil with acid and the like, and electrolytic copper-plating at a current density of 0.1 to 10 A/dm² with copper foil as a cathode electrode in a solution typically comprising copper sulfate as a predominant constituent to form. For example, the method is known in which 180 to 240 g/l of copper sulfate, 45 to 60 g/l of sulfuric acid and 20 to 80 g/l of chlorine ion, and thiourea, dextrin or thiourea and molasses as additives are added.

In the flash etching step of FIG. 2(h), the bare thin film copper except the copper wiring pattern part is removed by dipping or spraying with flash etching solution. As flash etching solution, the well-known ones may be used, and the examples thereof include solutions in which hydrogen peroxide is mixed with sulfuric acid or aqueous solutions comprising diluted ferric chloride as a main component, and for example, FE-830 made by Ebara Densan and AD-306E made by Asahi Denka Kogyo. Although here the copper of the circuit part (wiring) dissolves when removing the thin copper foil, no substantive defect is made because the amount of etching necessary to remove copper foil is small.

For half etching of the copper foil in FIG. 2(c), a well-known method may be appropriately used. For example, there may be used a method in which the copper foil laminated polyimide film is dipped into a well-known half etching solution or the solution is sprayed on the film to further thin the copper foil. As the half etching solution, the well-known ones may be used, and the example thereof include solutions in which hydrogen peroxide is mixed with sulfuric acid or those comprising sodium persulfate aqueous solution as a main component, and for example, DP-200 made by Ebara-Udylite and ADEKA TEC CAP made by Asahi Denka Kogyo.

For the copper-etching of FIG. 1(f), well-known copper-etching solution may be appropriately used, and the examples thereof include potassium ferricyanide aqueous solution, ferric chloride aqueous solution, copper chloride aqueous solution, ammonium persulfate aqueous solution, sodium persulfate aqueous solution, hydrogen peroxide solution, hydrofluoric aqueous solution and combinations of these.

The present invention is characterized by the washing step with the etching solution shown in FIG. 1(g) and FIG. 2(h). The etching solution used, as already described, may be those capable of removing at least one metal selected from Ni, Cr, Co, Zn, Sn and Mo or an alloy comprising at least one of these metals. For the purpose of roughening treatments, anti-corrosion treatments, heat-resistant treatments, chemical resistant treatments and so on, the carrier-accompanied copper foil is generally surface-treated with at least one metal selected from Ni, Cr, Co, Zn, Sn and Mo or an alloy comprising at least one of these metals (hereafter, the metal used for the surface-treatment is referred to as surface-treatment metal), and, thus, these metals exist on the metal foil surface. The present invention intends, in the washing step, to completely remove the surface-treatment metal that potentially remains on the polyimide film surface by usual etching.

Therefore, the etching solutions used in the washing step according to the present invention are those capable of removing the surface-treatment metal, and preferably an etching solution capable of removing the surface-treatment metal at a faster rate than copper. As a specific method for washing, a method for washing by dipping or spraying treatment is exemplified. In addition, the washing condition may be the condition to reduce the surface-treatment metal used for the surface-treatment of the copper foil on the polyimide film surface emerging by removing the copper foil, and it is preferably carried out at 30 to 60° C. within a range from 0.1 to 10 minutes.

As the etching solution for washing, as long as the etching solution is able to remove mainly the surface-treatment metal, well-known etching solution, such as Ni etching solution, Cr etching solution, Co etching solution, Zn etching solution, Sn etching solution, Mo etching solution, Ni—Cr etching solution, or acidic etching solution may be used, but not be limited to these.

As the etching solution, the etching agent for Ni—Cr alloy (the Ni—Cr seed layer remover) may be used, and the example thereof include, well-known etching solution such as MELSTRIP NC-3901 made by Meltex, ADEKA REMOVER NR-135 made by Asahi Denka Kogyo and FLICKER-MH made by Nihon Kagaku Sangyo. For example, acidic etching solution comprising hydrochloric acid, and alkaline etching solution comprising potassium ferricyanide or permanganate may also be used.

In particular, when at least a part of copper wiring is plated such as tin-plating, anomalous deposition of plating metal such as tin-plating does not occur or can be inhibited on the bare surface of the polyimide film or the site where the bare surface of the polyimide film contacts the copper wiring, and electrical insulating properties are improved. Furthermore, adhesiveness with adhesives such as epoxy resin and ACF is improved.

The copper wiring is preferably formed at not more than 80 μm in pitch, at not more than 50 μm in pitch, at not more than 40 μm in pitch, at not more than 30 μm in pitch, at not more than 20 μm in pitch, or at not more than 15 μm in pitch.

Next, a specific example of the method to form a circuit by the semi-additive method using the polyimide film laminated copper foil with carrier on its both sides is shown. Before or after stripping the carrier foil on at least one side, in the case of a both-sides laminating board, a through-hole or a blind via hole is formed by removing simultaneously the copper foil on the both sides and a part of the polyimide film with, for example, UV-YAG laser. Alternatively, the copper foil on the site of the polyimide film to be holed is removed beforehand by etching etc, and then the polyimide film may be removed by irradiating carbon dioxide laser to form a blind via, or a hole penetrating between the both sides may be formed by punching or drilling. If necessary, before or after forming the hole, the thin copper foil is further thinned by dipping the copper-clad laminate plate into a known half-etching solution or by spraying the liquid by a spraying equipment. As the half etching solution, for example, those in which hydrogen peroxide is mixed with sulfuric acid or those comprising sodium persulfate aqueous solution as a predominant constituent is raised, and for example, DP-200 made by Ebara-Udylite and ADEKA TEC CAP made by Asahi Denka Kogyo are exemplified. The step simultaneously forming wiring by the pattern-plating method and forming via by electrically connecting through the hole using electrolytic-plating method may be carried out by, for example, (i) forming conductive film in a through-hole or a blind via by the so-called DPS (Direct Plating System) method forming a palladium-tin film using palladium-tin colloid catalyst, (ii) laminating photo-type dry film plating-resist on both sides of the copper foil, (iii) exposing to light through a mask of a wiring pattern, (iv) spraying 1% sodium carbonate aqueous solution etc and developing to remove the plating-resist layer at the site to be the wiring pattern and the site to be the conductively connected hole, (v) washing a bare site of copper foil with acid etc, and (vi) carrying out electrolytic copper-plating at a current density of 0.1 to 10 A/dm² with copper foil as a cathode electrode. Thus, copper layer is formed in the hole and on the circuit site on both sides. Here, the RISERTRON DPS system made by Ebara-Udylite may be exemplified as the DPS step. Here, a surface treatment with an aqueous solution comprising monoethanolamine as a main agent makes a condition in which palladium-tin colloid catalyst readily adsorbs. Subsequently, the surface of the thin copper foil having readily-adsorbing property by treatment is removed with a soft-etching solution to inhibit formation of palladium-tin film on the copper foil surface and ensure adhesion strength of the copper foil surface and electrolytic plating. It is dipped into sodium chloride, hydrochloric acid and so on. After these steps, Pd—Sn film is formed in the activating step comprising dipping into palladium-tin colloid liquid. Reducing agent may be added to an alkaline accelerator bath used for activation during final activation in an alkaline accelerator bath containing sodium carbonate, potassium carbonate and copper ion, and an acid accelerator bath containing sulfuric acid. Examples of the reducing agent which may be added include, for example, aldehydes such as formaldehyde, acetaldehyde, propionaldehyde and benzaldehyde, and catechol, resorcin, ascorbic acid and so on. The alkaline accelerator bath to which the reducing agent is added preferably comprises sodium carbonate, potassium carbonate and copper ion. By the method already described, a low resistant film consisted of Pd—Sn may be obtained. As the aforementioned dry film, negative-type resist and positive-type resist may be included, and for example, SPG-152 made by Asahi Chemical Industry and RY-3215 made by Hitachi Kasei is exemplified as the negative-type plating-resist. As electrolytic copper-plating, there is a method in which for example, 180 to 240 g/l of copper sulfate, 45 to 60 g/l of sulfuric acid and 20 to 80 g/l of chlorine ion, and thiourea, dextrin or thiourea and molasses as additives are added. Then, after stripping and removing the plating-resist layer by spraying 2% sodium hydroxide aqueous solution, the bare thin film copper except the copper wiring pattern part is removed by dipping into or spraying flash etching solution. As flash etching solution, for example, are exemplified those in which hydrogen peroxide is mixed with sulfuric acid or aqueous solutions comprising diluted ferric chloride as a predominant constituent, and for example, is exemplified FE-830 made by Ebara Densan and AD-305E made by Asahi Denka Kogyo. Although here the copper of the circuit part also dissolves when removing the thin copper foil, there is no substantive problem because the amount of etching necessary to remove copper foil is small. Subsequently, a circuit board is obtained by dipping into or spraying treatment with chemical liquid to remove surface-treatment metal (for example, existing in the form of layer). As the aforementioned chemical liquid to remove surface-treatment metal, for example, is exemplified FLICKER-MH made by Nihon Kagaku Sangyo and ADEKA REMOVER NR-135 made by Asahi Denka Kogyo.

Then, a specific example of the method to form a circuit by the subtractive method using the polyimide film laminated copper foil with carrier on its both sides is shown. Before or after stripping the carrier foil on at least one side, a through-hole or a blind via hole in the case of a both-sides laminating board, or a blind via hole in the case of a multilayer board, is formed by removing simultaneously the copper foil on the both sides and a part of the polyimide film with, for example, UV-YAG laser. Alternatively, the copper foil on the site of the polyimide film to be holed is removed beforehand by etching etc, and then the polyimide film may be removed by irradiating carbon dioxide laser to form a blind via, or a hole penetrating between the both sides may be formed by punching or drilling. After forming holes, the step simultaneously thickening the thin copper foil by the pattern-plating method and forming via electrically connecting through the hole using the electrolytic-plating method may be carried out by, for example, (i) forming conductive film in a through-hole by the so-called DPS (Direct Plating System) method forming a palladium-tin film by using palladium-tin colloid catalyst, and (ii) carrying out electrolytic copper-plating, typically, at a current density of 0.1 to 10 A/dm² with copper foil as a cathode electrode in solution comprising copper sulfate as a main component. Thus, copper-thickening is carried out in the hole and on the both sides. Here, the RISERTRON DPS system made by Ebara-Udylite may be exemplified as the DPS step. Here, a surface treatment with an aqueous solution comprising monoethanolamine as a main agent makes a condition in which palladium-tin colloid catalyst readily adsorbs. Subsequently, the surface of the thin copper foil having readily-adsorbing property by treatment is removed with a soft-etching solution to inhibit formation of palladium-tin film on the copper foil surface and ensure adhesion strength of the copper foil surface and electrolytic plating. It is dipped into sodium chloride, hydrochloric acid and so on. After these steps, Pd—Sn film is formed in the activating step comprising dipping into palladium-tin colloid liquid. Reducing agent may be added to an alkaline accelerator bath used for activation during final activation in an alkaline accelerator bath containing sodium carbonate, potassium carbonate and copper ion, and an acid accelerator bath containing sulfuric acid. Examples of the reducing agent which may be added include, for example, aldehydes such as formaldehyde, acetaldehyde, propionaldehyde and benzaldehyde, and catechol, resorcin, ascorbic acid and so on. The alkaline accelerator bath to which the reducing agent is added preferably comprises sodium carbonate, potassium carbonate and copper ion. By the method already described, a low resistant film consisted of Pd—Sn may be obtained. Then, photo-type etching resist is formed on the copper foil, and exposed to light through a mask of a wiring pattern, 1% sodium carbonate aqueous solution etc is sprayed and developed to remove the etching resist layer at the site except to be the wiring pattern and to bare the copper layer. The above-mentioned photo-type etching resist is formed on the copper foil by typically thermally laminating a negative-type dry film-type resist, or applying and drying a positive-type liquid-type resist. In the case of the negative-type, an exposed site remains during developing, on the other hand, in the case of the positive-type, an unexposed site remains during developing. As the negative-type dry film-form resist, SPG-152 made by Asahi Chemical Industry and RY-3215 made by Hitachi Kasei and so on may be used. Then, the bare site of the copper foil is etched and removed with typically ferric chloride solution to form a wiring pattern. Then, after removing the etching resist layer by spraying 2% sodium hydroxide aqueous solution etc, a circuit board is obtained by dipping into or spraying treatment with chemical liquid to remove surface-treatment metal (for example, existing in the form of layer). As the above-mentioned chemical liquid to remove surface-treatment metal, for example, is exemplified FLICKER-MH made by Nihon Kagaku Sangyo and ADEKA REMOVER NR-135 made by Asahi Denka Kogyo.

For the carrier-accompanied copper foil, as already described, at least one side to be laminated to the polyimide film is preferably surface-treated, such as roughening treatment, anti-corrosion treatment, heat-resistant treatment or chemical resistant treatment, with at least one metal selected from Ni, Cr, Co, Zn, Sn and Mo or an alloy comprising at least one of these metals. Furthermore, the surface is preferably silane-coupling treated.

The carrier-accompanied copper foil is not limited in particular, but preferably those may be used are copper, copper alloy and the like, such as electrolytic copper foil, rolled copper foil, having not more than 100 μm, preferably 0.1 to 100 μm, particularly 1 to 100 μm in thickness. The surface roughness of the copper foil laminated to the polyimide is not limited in particular.

The materials of the carrier foil are not limited in particular and may be used as long as they can be stuck to copper foil such as extremely-thin copper foil, and function so as to reinforce and protect the extremely-thin copper foil, and be readily peeled from the copper foil. For example, aluminum foil, copper foil, resin foil with metal-coated surface and the like may be used. The thickness of the carrier foil is not limited in particular, but may be used as long as they can reinforce thin copper foil, and generally may be preferably used with 15 to 200 μm in thickness. Protection foil (carrier foil) may be used so as to be planarly stuck to extremely-thin metal foil such as extremely-thin copper foil. In the case of the carrier-accompanied electrolytic copper foil, since copper components are electrodeposited on the carrier foil surface to form electrolytic copper foil, carrier foil needs to have conductivity at least.

The carrier foil that can be used is those that travel through a series of manufacturing steps, and keep juncture with the copper foil layer at least until completion of producing the copper foil laminated polyimide film, and facilitate handling. The carrier foil, which may be used, is removed by peeling after laminating the carrier foil-accompanied copper foil to the polyimide foil, or may be removed by etching after laminating the carrier foil-accompanied copper foil to the polyimide foil.

For the polyimide film, its linear expansion coefficient (50 to 200° C.) is preferably close to a thermal expansion coefficient of copper foil to be laminated to the polyimide film, and the thermal expansion coefficient of the polyimide film is preferably 0.5×10⁻⁵ to 2.8×10⁻⁵ cm/cm/° C. If, for the polyimide film, one with its heat shrinkage factor of not more than 0.05% is used, it is preferable due to small heat-distortion. For the polyimide film, it may be used in the form of mono-layer, multi-layer film laminated with two or more layers and a sheet. For the polyimide film, one having excellent heat resistance and electrical insulation may be preferably used.

The thickness of the polyimide film is not limited in particular, but it preferably may be in the range so that laminating with the carrier foil-accompanied copper foil can be done without any problem, manufacturing and handling can be done, and the copper foil can be sufficiently supported. Preferably it is 1 to 500 μm, more preferably 2 to 300 μm, furthermore preferably 5 to 200 μm, more preferably 7 to 175 μm, particularly preferably 8 to 100 μm.

As the polyimide film used herein, substrates surface-may be treated by such as corona discharge treatment, plasma treatment, chemical roughening treatment, physical roughening treatment and the like at least on one side of the substrate.

The polyimide film may be prepared by a known method, and for example, for mono-layer polyimide film, the following method may be utilized:

(1) The method of flow-casting or applying a solution of a poly(amic acid) as a polyimide precursor on a support, and imidizing it,

(2) The method of flow-casting or applying a polyimide solution on a support, and then, if necessary, heating it.

For two or more layers polyimide film, the following method may be utilized:

(3) The method of flow-casting or applying a solution of a poly(amic acid) as a polyimide precursor on a support, and furthermore flow-casting or applying successively a solution of a poly(amic acid) as a polyimide precursor for the second or later layer on the upper face of the previous poly(amic acid) layer flow-casted or applied on the support, and imidizing them,

(4) The method of simultaneously flow-casting or applying solutions of a poly(amic acid) for two or more layers as a polyimide precursor on a support, and imidizing them,

(5) The method of flow-casting or applying a polyimide solution on a support, and furthermore successively flow-casting or applying a polyimide solution for the second or later layer on the upper face of the previous polyimide layer flow-casted or applied on the support, and, if necessary, heating them,

(6) The method of simultaneously flow-casting or applying polyimide solutions for two or more layers on a support, and, if necessary, heating them,

(7) The method of laminating two or more polyimide films obtained by the above methods (1) to (6) directly or through adhesive.

When the carrier-accompanied copper foil and the polyimide film are laminated, a heating machine, a compression machine or a thermocompression machine may be used, and preferably a heating or compression condition is appropriately selected depending on materials to be used. Although the production process is not particularly limited as long as continuous or batch laminating is employable, it is preferably carried out continuously by using a roll laminating or a double-belt press and the like.

As an embodiment of the production method of the carrier-accompanied copper foil laminated polyimide film, the following methods are exemplified.

1) Lengthy carrier-accompanied copper foil, lengthy polyimide film and lengthy carrier-accompanied copper foil are piled in three layers in this order, and furthermore protection film is piled outside if needed, and they are fed to a compression-bonding machine. In this process, they are preferable pre-heated at about 150 to 250° C., particularly at a temperature higher than 150° C. and 250° C. or lower for about 2 to 120 sec in line immediately before introducing in the machine by preferably using a pre-heater such as a hot-air blower or an infrared heating machine.

2) By using a pair of compression-bonding rolls or a double-belt press, the three-ply of carrier-accompanied copper foil/polyimide film/carrier-accompanied copper foil is thermally bonded under pressure, wherein a temperature in a heating and compression-bonding zone of the compression-bonding rolls or the double-belt press is within a range of higher by 20° C. or more than a glass transition temperature of polyimide and below 400° C., particularly higher by 30° C. or more than the glass transition temperature and below 400° C.

3) In particularly the case of a double-belt press, the laminate is successively cooled while being pressed in a cooling zone to a temperature lower by 20° C. or more, particularly by 30° C. or more than the glass transition temperature of the polyimide to complete lamination, and rewinded in a roll form. Thus, the roll-form both sides carrier-accompanied copper foil laminated polyimide film can be produced.

The polyimide film used herein has thermocompression-bondable property and has two or more layers, i.e. thermocompression-bondable polyimide (S2) layer(s) on at least one sides of a heat-resistant polyimide layer (S1). As an example of layer constitution of the multi-layers polyimide film, S2/S1, S2/S1/S2, S2/S1/S2/S1, S2/S1/S2/S1/S2 and so on are exemplified.

In the polyimide film having thermocompression-bondable property, thicknesses of the heat-resistant polyimide layer (S1) and the thermocompression-bondable polyimide (S2) may be appropriately selected, and the thickness of the thermocompression-bondable polyimide (S2) of the top-surface layer of the thermocompression-bondable polyimide film is within a range of 0.5 to 10 μm, preferably 1 to 7 μm, more preferably 2 to 5 μm. Curling can be reduced by forming the thermocompression-bondable polyimide layers (S2) having almost the same thickness on the both sides of the heat-resistant polyimide layer (S1).

In the polyimide film having thermocompression-bondable property, heat-resistant polyimide used for the heat-resistant polyimide layer (S1 layer), may be selected from those having at least one of the following properties, or those having at least two of the following properties {i.e. the combination of 1) and 2), 1) and 3) or 2) and 3)}, particularly from those having all of the following properties.

1) In the case of polyimide film alone, a glass transition temperature is 300° C. or higher, preferably 330° C. or higher, and further preferably, a glass transition temperature is undetectable.

2) In the case of polyimide film alone, a linear expansion coefficient (50 to 200° C.) (MD) is close to a thermal expansion coefficient of a metal foil such as a copper foil laminated on the polyimide film, and when using a copper foil as a metal foil, a thermal expansion coefficient of the polyimide film is preferably 5×10⁻⁶ to 28×10⁻⁶ cm/cm/° C., more preferably 9×10⁻⁶ to 20×10⁻⁶ cm/cm/° C., further preferably 12×10⁻⁶ to 18×10⁻⁶ cm/cm/° C.

3) In the case of polyimide film alone, a tensile modulus (MD, ASTM-D882) is 300 kg/mm² or more, preferably 500 kg/mm² or more, further preferably 700 kg/mm² or more.

As the heat-resistant polyimide layer (S1) in the polyimide film having thermocompression-bondable property, such polyimide may be used that prepared from the combination of acid component predominantly comprising 3,3′,4,4′-biphenyltetracarboxylic dianhydride (s-BPDA), pyromellitic dianhydride (PMDA) and 3,3′,4,4′-benzophenonetetracarboxylic dianhydride (BTDA), and a diamine component predominantly comprising p-phenylenediamine (PPD) and 4,4′-diaminodiphenyl ether (DADE). The preferable examples are listed as follows.

(1) The polyimide produced from 3,3′,4,4′-biphenyltetracarboxylic dianhydride (s-BPDA) and p-phenylenediamine (PPD) and optionally 4,4′-diaminodiphenyl ether (DADE). In this case, a ratio of PPD/DADE (molar ratio) is preferably 100/0 to 85/15.

(2) The polyimide produced from 3,3′,4,4′-biphenyltetracarboxylic dianhydride and pyromellitic dianhydride and p-phenylenediamine and 4,4′-diaminodiphenyl ether. In this case, a ratio of BPDA/PMDA is preferably 15/85 to 85/15 and a ratio of PPD/DADE is preferably 90/10 to 10/90.

(3) The polyimide produced from pyromellitic dianhydride, p-phenylenediamine and 4,4′-diaminodiphenyl ether. In this case, a ratio of DADE/PPD is preferably 90/10 to 10/90.

(4) The polyimide produced from 3,3′,4,4′-benzophenonetetracarboxylic dianhydride (BTDA) and pyromellitic acid dianhydride and 4,4′-diaminodiphenyl ether. In this case, a ratio of BTDA/PMDA in acid dianhydrides is preferably 20/80 to 90/10 and a ratio of PPD/DADE in diamines is preferably 30/70 to 90/10.

The synthesis of the heat-resistant polyimide for the heat-resistant polyimide layer (S1 layer) is accomplished by any method such as random polymerization, or block polymerization or the method including combining solutions of two kinds of poly(amic acid) synthesized beforehand, and mixing under the reaction condition to give a uniform solution.

In the synthesis of the heat-resistant polyimide, by using the aforementioned each component, the almost-equimolar amounts of diamine components and dianhydrides are reacted in an organic solvent to give a poly(amic acid) solution (it may be partially imidized as long as uniform solution condition is kept).

Other tetracarboxylic dianhydrides or diamines, of which the kind and the amount are chosen so as not to degrade the properties of the heat-resistant polyimide, may be used.

On the other hand, the thermocompression-bondable polyimide for the thermocompression-bondable polyimide layer (S2) is a polyimide 1) which has thermocompression-bondable property to metal foil, preferably is thermocompression-bondable by laminating with metal foil at a temperature not lower than a glass transition temperature of the thermocompression-bondable polyimide (S2) and not higher than 400° C.

Furthermore, the thermocompression-bondable polyimide of the thermocompression-bondable polyimide layer (S2) preferably has at least one of the following properties.

2) A thermocompression-bondable polyimide (S2) has a peel strength between a metal foil and the polyimide (S2) of 0.7 N/mm or more, and the retention of a peel strength after heat treatment at 150° C. for 168 hours is 90% or more, further 95% or more, particularly 100% or more.

3) Its glass transition temperature is from 130 to 330° C.

4) Its tensile modulus is 100 to 700 Kg/mm².

5) Its linear expansion coefficient (50 to 200° C.) (MD) is 13 to 30×10⁻⁶ cm/cm/° C.

The thermocompression-bondable polyimide of the thermocompression-bondable polyimide layer (S2) may be selected from known thermoplastic polyimides. For example, there may be used a polyimide prepared from

an acid component comprising at least one selected from acid dianhydrides such as 2,3,3′,4′-biphenyltetracarboxylic dianhydride (a-BPDA), 3,3′,4,4′-biphenyltetracarboxylic dianhydride (s-BPDA), pyromellitic dianhydride (PMDA), 3,3′, 4,4′-benzophenonetetracarboxylic dianhydride (BTDA), 3,3′,4,4′-diphenylsulfonetetracarboxylic dianhydride, 4,4′-oxydiphthalic dianhydride (ODPA), p-phenylenbis(trimellitic monoester anhydride), 3,3′,4,4′-ethyleneglycoldibenzoatetetracarboxylic dianhydride, preferably comprising them as a main component, and

a diamine component having at least three benzene rings in its main chain, comprising at least one selected from diamines such as 1,4-bis(4-aminophenoxy) benzene, 1,3-bis(4-aminophenoxy) benzene, 1,3-bis(3-aminophenoxy) benzene, 2,2-bis[4-(4-aminophenoxy) phenyl] propane, 2,2-bis[4-(3-aminophenoxy) phenyl] propane, bis[4-(4-aminophenoxy) phenyl] sulfone, bis[4 (3-aminophenoxy) phenyl] sulfone, preferably comprising them as a main component, and further comprising a diamine component having one or two benzene rings in its main chain if needed.

The thermocompression-bondable polyimide preferably used herein is polyimide prepared from preferably an acid component selected from 2,3,3′,4′-biphenyltetracarboxylic acid dianhydride (a-BPDA), 3,3′,4,4′-biphenyltetracarboxylic acid dianhydride (s-BPDA), pyromellitic acid dianhydride (PMDA) and 3,3′,4,4′-benzophenonetetracarboxylic acid dianhydride (BTDA), and a diamine component selected from 1,4-bis(4-aminophenoxy) benzene, 1,3-bis(4-aminophenoxy) benzene, 1,3-bis(3-aminophenoxy) benzene and 2,2-bis[4-(4-aminophenoxy) phenyl] propane. If needed, a diamine component having one or two benzene rings in its main chain, and diamine and acid components other than described above may be comprised.

Particularly preferred is those prepared from a diamine component comprising 80 mol % or more of 1,3-bis(4-aminophenoxy) benzene (hereafter, may be referred as TPER) and 3,3′,4,4′-biphenyltetracarboxylic dianhydride and 2,3,3′,4′-biphenyltetracarboxylic acid dianhydride (hereafter, may be referred as a-BPDA). In this case, s-BPDA/a-BPDA is preferably 100/0 to 5/95, and may be replaced with other tetracarboxylic acid dianhydrides for example, 2,2-bis(3,4-dicarboxyphenly)propane acid dianhydride, 2,3,6,7-naphtarentetracarboxylic dianhydride and so on, in such an amount that the properties of the thermocompression-bondable polyimide is degraded.

The thermocompression-bondable polyimide may be prepared by a method in which each the aforementioned component and further other tetracarboxylic acid dianhydrides and other diamines are reacted in a organic solvent at a temperature not higher than 100° C., particularly 20 to 60° C. to give a poly(amic acid) solution, and then using this poly(amic acid) solution as a dope liquid, the film of the dope liquid is formed, and its solvent is evaporated from the film and at the same time poly(amic acid) is imide-cyclized. Alternatively, the organic solvent solution of the thermocompression-bondable polyimide may be obtained by heating the poly(amic acid) solution prepared as above at 150 to 250° C., or adding imidization agent at 150° C. or lower, particularly reacting at 15 to 50° C., and followed by evaporating solvent after imidization, or followed by precipitation in poor solvent to give powder and dissolving the powder in organic solution.

To obtain the thermocompression-bondable polyimide, the ratio of amount of diamines (as a mole of amino groups) to the total mole of acid anhydrides (as the total mole of acid anhydride groups of tetra acid dianhydrides and dicarboxylic acid anhydrides) is preferably 0.95 to 1.0, particularly 0.98 to 1.0, particularly among them 0.99 to 1.0. When dicarboxylic acid anhydrides are used, their amount as the ratio of tetra acid dianhydrides to the mole of acid anhydride groups is 0.55 or lower so that individual components can be reacted.

When molecular weight of the poly(amic acid) obtained is low in the production of the thermocompression-bondable polyimide, the adhesion strength to the metal foil in the laminate may be lowered.

In addition, for the purpose to restrict gelation of the poly(amic acid), phosphorus-base stabilizer, for example, triphenyl phosphite, triphenyl phosphate and so on may be added within a range of 0.01 to 1% of solids (polymer) during polymerization of the poly(amic acid).

In addition, for the purpose to promote imidization, a basic organic compound may be added to the dope liquid. For example, imidazole, 2-imidazole, 1,2-dimethylimidazole, 2-phenylimidazole, benzimidazole, isoquinoline, substituted-pyridine and so on may be used in a proportion of 0.05 to 10 wt %, particularly 0.1 to 2 wt % of the poly(amic acid). Since these can form polyimide film at a relatively low temperature, these may be used to avoid insufficient imidization. In addition, for the purpose to stabilize the adhesion strength, organic aluminum compounds, inorganic aluminum compounds or organic tin compounds may be added to the poly(amic acid) solution for the polyimide. For example, aluminum hydroxide, aluminum triacetylacetonate and so on may be added at 1 ppm or more, particularly 1 to 1000 ppm as aluminum metal to the poly(amic acid).

As for the organic solvent used for producing the poly(amic acid) from the acid component and diamine component, for both of the heat-resistant polyimide and the thermocompression-bondable polyimide, are exemplified N-methyl-2-pyrrolidone, N, N-dimethylformamide, N, N-dimethylacetamide, N, N-diethylacetamide, dimethylsulfoxide, hexamethylphosphoramide, N-methylcaprolactam, cresols. These organic solvents may be used alone or more than two kinds together.

For both of the heat-resistant polyimide and the thermocompression-bondable polyimide, in order to block their terminal, dicarboxylic anhydrides may be used, such as phthalic anhydride and its substitution product, hexahydrophthalic anhydride and its substitution product, succinic anhydride and its substitution product and so on, particularly phthalic anhydride.

The polyimide film having thermocompression-bondable property may be obtained preferably by a method (i) or (ii), i.e.

(i) By the coextrusion-flow-casting film formation method (also being simply referred to as multi-layers extrusion), the dope liquid of the heat-resistant polyimide (S1) and the dope liquid of the thermocompression-bondable polyimide (S2) is laminated, dried and imidized to give multi-layers polyimide film, or
(ii) the dope liquid of the heat-resistant polyimide (S1) is flow-cast on a support, and dried to give self-supporting film (gel film), and next, on one side or both sides thereof, the dope liquid of the thermocompression-bondable polyimide (S2) is applied, and dried and imidized to give the multi-layers polyimide film.

For the coextrusion method, may be used the method described in the Japanese Laid-open Patent Publication No. H03-180343 (Japanese Kokoku Patent Publication No. H07-102661).

An embodiment of the production of three-layer polyimide film having thermocompression-bondable properties on both sides is indicated. The poly(amic acid) solution of the polyimide (S1) and the poly(amic acid) of polyimide (S2) are supplied to a three-layer extrusion molding die by three-layer coextrusion method so that the thickness of the heat-resistant polyimide layer (S1 layer) is 4 to 45 μm and the thickness of the thermocompression-bondable polyimide layer (S2 layer) on both sides is 3 to 10 μm in the total, and cast on a support and this is flow-cast and applied on a smooth support surface such as a stainless mirror surface and a stainless belt surface, and at 100 to 200° C. the polyimide film A as a self-supporting film is obtained in a semi-cured state or a dried state before the semi-curing.

For the polyimide film A as a self-supporting film, if a flow-casted film is treated at a temperature higher than 200° C., some defects tend to occur such as decrease in adhesiveness during preparation of the polyimide film having thermocompression-bondable property. This semi-cured state or the state before the semi-curing means a self-supporting state by heating and/or chemical imidization.

The polyimide film A as a self-supporting film obtained is heated at a temperature not lower than the glass transition temperature of polyimide (S2) and not higher than degradation-occurring temperature, preferably a temperature from 250 to 420° C. (surface temperature measured by a surface thermometer) (preferably heating at this temperature for 0.1 to 60 min.), and dried and imidized. Thus, the polyimide film having the thermocompression-bondable polyimide layer (S2 layer) on both sides of the heat-resistant polyimide layer (S1 layer) is produced.

In the polyimide film A as a self-supporting film obtained, solvent and generated water remains preferably at about 25 to 60 mass %, particularly preferably 30 to 50 mass %. The self-supporting film is preferably heated-up for relatively short period when it is heated-up to a drying temperature, for example, heating rate is not lower than 10° C./min preferably. When drying, by increasing tension applied for the self-supporting film, the linear expansion coefficient of polyimide film A finally obtained may be reduced.

Then, following the above-mentioned drying step, the self-supporting film is continuously or intermittently dried and heat-treated, in a condition in which a pair of side edge of the self-supporting film is fixed by a fixing equipment at least mobile continuously or intermittently together with the self-supporting film, at a high temperature higher than the drying temperature, preferably within a range from 200 to 550° C., particularly preferably within a range from 300 to 500° C., and preferably for 1 to 100 min., particularly 1 to 10 min. The polyimide film having thermocompression-bondable property on both sides may be formed by sufficiently removing solvent etc from the self supporting film and at the same time sufficiently imidizing the polymer consisting of the film so that the contents of volatile components consisted of organic solvents and generated water is not more than 1 wt %.

The fixing equipment of the self-supporting film preferably used herein is equipped with a pair of belt or chain having many pins or holders at even intervals, along longitudinal both side of the solidified film supplied continuously or intermittently, and is able to fix the film while the pair of belt or chain is continuously or intermittently moved with movement of the film. In addition, the fixing equipment of the above solidified film may be able to extend or shrink the film under heat treatment with suitable extension ratio or shrinkage ratio across-the-width or longitudinal (particularly preferably about 0.5 to 5% of extension or shrinkage ratio).

The polyimide film having thermocompression-bondable property on both sides having particularly excellent dimension stability may be obtained by heat-treating again the polyimide film having thermocompression-bondable property on both sides under low or no tension preferably not higher than 4N, particularly preferably not higher than 3N at a temperature of 100 to 400° C., and preferably for 0.1 to 30 min. In addition, thus produced lengthy polyimide film having thermocompression-bondable property on both sides may be rewound in a roll form by an appropriate known method.

When the carrier-accompanied copper foil, and the polyimide film laminated with the thermocompression-bondable polyimide layer on at least one side of the high heat-resistant polyimide layer are laminated, a heating machine, a compression machine or a thermocompression machine may be used, and preferably a heating or compression condition is appropriately selected depending on materials to be used. Although the production process is not particularly limited as long as continuous or batch laminating is employable, it is preferably carried out continuously by using a roll laminating or a double-belt press and the like.

The carrier-accompanied copper foil laminated polyimide film may be produced by laminating the surface-treated side of the copper foil, preferably by using the above-mentioned polyimide film on the both sides or one side of which the thermocompression-bondable polyimide layer (S2 layer) is formed.

As an embodiment of the production method of the carrier-accompanied copper foil laminated polyimide film, the following methods are exemplified.

1) Lengthy carrier-accompanied copper foil, the lengthy polyimide film having thermocompression-bondable property and lengthy carrier-accompanied copper foil are piled in this order, and furthermore protection film is piled outside if needed, and they are fed to a thermocompression machine. In this, they are preferable pre-heated at about 150 to 250° C., particularly at a temperature higher than 150° C. and 250° C. or lower for about 2 to 120 sec in line immediately before introducing in the machine by preferably using a pre-heater such as a hot-air blower or an infrared heating machine.

2) By using a pair of compression-bonding rolls or a double-belt press, the three-ply of carrier-accompanied copper foil/polyimide film/carrier-accompanied copper foil is thermally bonded under pressure, wherein a temperature in a heating and compression-bonding zone of the compression-bonding rolls or the double-belt press is within a range of higher by 20° C. or more than a glass transition temperature of polyimide (S2) and below 400° C., particularly higher by 30° C. or more than the glass transition temperature and below 400° C.

3) In particularly the case of a double-belt press, the laminate is successively cooled while being pressed in a cooling zone to a temperature lower by 20° C. or more, particularly by 30° C. or more than the glass transition temperature of the polyimide (S2) to complete lamination, and rewinded in a roll form. Thus, the roll-form both sides carrier-accompanied copper foil laminated polyimide film can be produced.

In this production method, the pre-heating of the polyimide film before thermocompression-bondable is effective to prevent the occurrence of defective appearance by laminate's foaming after thermocompression-bondable or foaming when soaking in a solder bath during formation of electronic circuits due to moisture the polyimide contains. Thus, decreasing in production yield can be prevented.

The double-belt press can perform heating to high temperature and cooling down while applying pressure, and a hydrostatic type using heat carrier is preferable. In the production of both sides carrier-accompanied copper foil laminated polyimide film, lamination is carried out preferably at a drawing rate of 1 m/min or more by thermocompression-bonding and cooling under pressure using a double-belt press. Thus obtained both sides carrier-accompanied copper foil laminated polyimide film is continuously long and have a width of about 400 mm or more, particularly about 500 mm or more, and high adhesive strength (the peel strength of the metal foil and the polyimide layer is 0.7 N/mm or more, and the retention rate of the peel strength is 90% or more after heating treatment at 150° C. and for 168 hour), and further has good appearance so that substantially no wrinkles are observed.

In the present invention, in order to mass-produce the both sides carrier-accompanied copper foil laminated polyimide film with good appearance, while one or more combinations of the polyimide film having thermocompression-bondable property and the copper foil is being supplied, protectors are placed between top-surface layer at both sides and the belts (i.e., two sheets of protector), and these together are preferably bonded and laminated by thermocompression-bonding and cooling under pressure. For the protector, its material is particularly not limited for use as long as it is non-thermocompression-bondable and have a good surface smoothness, and the preferred examples thereof include metal foil, particularly copper foil, stainless foil, aluminum foil, and high heat resistant polyimide film (Upilex made by Ube Industries, Kapton H made by DuPont-TORAY) and the like having about 5 to 125 μm in thickness.

As the copper-wiring polyimide film, there may also be used those having the above-described heat-resistant polyimide (S1) on at least one side of which the surface-treated face of copper foil is laminated through adhesive. In the copper-wiring polyimide film, when the heat-resistant polyimide (S1) and the metal foil are laminated through adhesive, the adhesive may be thermosetting or thermoplastic. The examples of thermosetting adhesive include epoxy resin, NBR-phenol-based resin, phenol-butyral-based resin, epoxy-NBR-based resin, epoxy-phenol-based resin, epoxy-nylon-based resin, epoxy-polyester-based resin, epoxy-acryl-based resin, acryl-based resin, polyamide-epoxy-phenol-based resin, polyimide-based resin, polyimidesiloxane-epoxy resin, and the examples of thermoplastic adhesive include polyamide-based resin, polyester-based resin, polyimide-based adhesive, polyimidesiloxane-based adhesive. In particular, polyimide adhesive, polyimidesiloxane-epoxy adhesive, epoxy resin adhesive may be preferably used.

The copper-wiring polyimide film etched and washed and the copper-wiring polyimide film in which at least a part of copper wiring is plated may be utilized as flexible wiring circuit substrates, built-up circuit substrates, or IC carrier tape substrates in the field of every electronics such as computers, terminal machines, telephones, communications equipments, measurement control machines, cameras, clocks, cars, office appliances, household electrical appliances, airplane instruments, medical equipments.

In the present invention, it is presumed that plating abnormality is restrained because the surface treatment metal existing on the polyimide film surface emerged after the removal of the copper foil is removed.

### EXAMPLES

The present invention will be more specifically described with reference to the following Examples. However, the present invention is not limited to these Examples.

Physical property evaluation was conducted in accordance with the methods below.

1) Glass transition temperature (Tg) of polyimide film: determined from a peak tan δ value by a dynamic viscoelasticity method (tensile method; frequency: 6.28 rad/sec; temperature rising rate: 10° C./min).

2) Linear expansion coefficient (50 to 200° C.) of polyimide film: an average linear expansion coefficient at 20 to 200° C. is determined by a TMA method (tensile method; temperature rising rate: 5° C./min).

3) Peel strength of metal foil laminated polyimide film (as made), peel strength of polyimide film and adhesion tape: in accordance with JIS-C6471, a lead with 3 mm in width defined in the same test method was made, and for nine test pieces each from metal of roll inner side and roll outer side, the 90° peel strength was measured at crosshead speed of 50 mm/min. For the polyimide film and the copper foil laminated polyimide film, its peel strength is an average of nine values. For the laminate of the polyimide film and the adhesive sheet, its peel strength is an average of three values. If the thickness of the metal foil is less than 5 μm, it is electroplated by 20 μm of thickness, and the measurement is carried out. (Roll inner means peel strength of inside of the metal foil laminated polyimide film rewound, and roll outer means peel strength of outside of the metal foil laminated polyimide film rewound.)

4) Peel strength of metal foil laminated polyimide film (after heating at 150° C. and for 168 hours): in accordance with JIS-C6471, a lead with 3 mm in width defined in the same test method was made, and after placing three test pieces in an air circulation thermostatic oven at 150° C. and for 168 hours, the 90° peel strength was measured at crosshead speed of 50 mm/min. The peel strength was an average of three values. If the thickness of the metal foil is less than 5 μm, it is electroplated by 20 μm of thickness, and the measurement is carried out.

The retention rate of peel strength after heating treatment at 150° C. and for 168 hours was calculated in accordance with the numerical formula (1) below. (Roll inner means peel strength of inside of the metal foil laminated polyimide film rewound, and roll outer means peel strength of outside of the metal foil laminated polyimide film rewound.)

X(%)=Z/Y×100 (1)

(X is the retention rate of peel strength after heating treatment at 150° C. and for 168 hours, Y is the peel strength before heating, and Z is the peel strength after heating treatment at 150° C. and for 168 hours.)

5) Insulation breakdown voltage of polyimide film: determined in accordance with ASTM-D149 (the voltage when insulation broke down was measured by increasing voltage at a rate of 1000V/sec). It was measured in air when the thickness of polyimide was up to 50 μm, and measured in oil when the thickness was 50 μm or thicker.

6) Inter-wiring insulation resistance, volume resistance of metal foil laminated polyimide film: determined in accordance with JIS-C6471.

7) Mechanical properties of polyimide film
Tensile strength: determined in accordance with ASTM-D882 (cross-head speed: 50 mm/min).
Elongation percentage: determined in accordance with ASTM-D882 (cross-head speed: 50 mm/min).
Tensile modulus: determined in accordance with ASTM-D882 (cross-head speed: 5 mm/min).

### Reference Example 1

### Production of Polyimide S1

In N-methyl-2-pyrrolidone, para-phenylenediamine (PPD) and 3,3′,4,4′-biphenyltetracarboxylic dianhydride (s-BPDA) were added in a molar ratio of 1000:998 such that a monomer concentration was 18% (weight %, the same hereinafter), and then the mixture was reacted at 50° C. for 3 hours. The obtained poly(amic acid) solution had a solution viscosity of about 1680 poises at 25° C.

### Reference Example 2

### Production of Polyamide S2

In N-methyl-2-pyrrolidone, 1,3-bis(4-aminophenoxy) benzene (TPE-R) and 2,3,3′,4′-biphenyltetracarboxylic dianhydride (a-BPDA) and 3,3′,4,4′-biphenyltetracarboxylic dianhydride (s-BPDA) were added in a molar ratio of 1000:200:800 such that a monomer concentration was 18%, and further was added triphenyl phosphate in 0.5% by weight relative to the monomers, and then the mixture was reacted at 40° C. for 3 hours. The obtained poly(amic acid) solution had a solution viscosity of about 1680 poises at 25° C.

### Reference Example 3

### Production of Polyamide Film A1

The poly(amic acid) solutions obtained from the reference examples 1 and 2 were flow-casted on a metal support by using a film-forming equipment provided with a three-layer extrusion die (multi-manifold type die) while varying a thickness of the three-layer extrusion die, and after continuously drying under hot air at 140° C., by peeling the self-support film was formed. After peeling this self-support film from the support, solvent was removed by gradually heating from 150° C. to 450° C. in a heating furnace, and imidization was carried out, and the resulting long three-layer polyimide film was wound onto a roll.

Properties of the three-layer polyimide film (S2/S1/S2) obtained were evaluated.
Thickness pattern: 4 μm/17 μm/4 μm (total 25 μm)
Glass transition temperature of the S2 layer: 240° C., glass transition temperature of the S1 layer: 340° C. or higher, definite temperature was not detected.
Linear expansion coefficient (50 to 200° C.): MD 19 ppm/° C., TD 17 ppm/° C.
Mechanical properties

1) Tensile strength: MD, TD 520 MPa

2) Coefficient of extension: MD, TD 100%

3) Tensile modulus: MD, TD 7100 MPa
Electrical properties

1) Breakdown voltage: 7.2 kV

2) Dielectric constant (1 GHz): 3.20

3) Dielectric tangent (1 GHz): 0.0047

### Example 1

### Process for Forming Circuit Through the Semi-Additive Method Using Carrier-Accompanied Copper Foil

Rolled-up carrier-accompanied copper foil made by Nippon Denkai (YSNAP-3B: carrier thickness 18 μm, thin copper foil 3 μm), the polyimide film A1 (three layer structure of S2/S1/S2) obtained in Reference Example 3, which was pre-heated by hot air at 200° C. for 30 sec in line immediately before a double-belt press, and Upilex S (made by Ube Industries, polyimide film, 25 μm) were laminated, provided to a heating zone (the highest heating temperature: 330° C.) and then provided to a cooling zone (the lowest cooling temperature: 180° C.). Thus, the lamination was completed successively thermocompression-bonding and cooling with a compression-bonding pressure: 3.9 MPa and a compression-bonding time: 2 min, which was then wound around a wind-up roll to form rolled-up polyimide film (width: 540 mm, length: 1000 m), in which carrier-accompanied copper foil has been laminated on one side.

Washing with Ni—Cr Seed Layer Remover

From the rolled-up one-side carrier-accompanied copper foil laminated polyimide film, a 10.5×25 cm rectangular sample was cut out, and the carrier foil was stripped.

Using DP-200 made by Ebara-Udylite as a half etching solution, the copper foil of the copper foil laminated polyimide film from which the carrier foil was striped was dipped at 25° C. and for 3 min. so that thickness of the copper foil became 1 μm.

After laminating dry film-type negative-type photoresist (SPG-152 made by Asahi Chemical Industry) on the half-etching treated copper foil by a thermal roll at 110° C., a site other than the portion where circuit (wiring pattern) is intended to be formed was exposed, and unexposed resist was spray-developed with 2% sodium carbonate aqueous solution and removed, and after degreasing and acid-washing the bare site of the thin copper foil, electrolytic copper-plating was conducted in a copper sulfate bath with the copper foil as a cathode electrode at a current density of 2 A/dm² at 25° C. for 30 min., pattern-plating of copper plating with 10 μm in thickness was carried out. Subsequently, after stripping the resist layer by spray-treatment with 2% sodium hydroxide aqueous solution at 42° C. for 15 seq, the copper foil in an unnecessary site was removed by spray-treatment with flash etching solution (AD-305E made by Asahi Denka Kogyo) at 30° C. for 20 sec. This sample was dipped into FLICKER-MH made by Nihon Kagaku Sangyo as Ni—Cr seed layer remover at 45° C. for 5 min., then copper-wiring was tin-plated using Tinposit LT-34H made by SHIPLEY at 80° C. for 4 min. The pitch of the copper wiring is 30 μm.

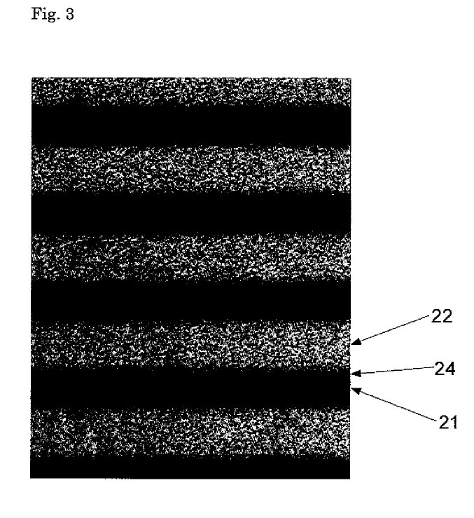

With respect to the tin-plated copper wiring and the polyimide film surface where the copper foil was removed between copper wirings of the tin-plated copper-wiring polyimide film, an image of a metallographic microscope (lens magnification: 500 times) was obtained, which is shown in FIG. 3. From FIG. 3, the polyamide surface where the copper foil was removed between copper wirings was clean, and no occurrence of anomalous metal deposition by tin-plating at the junction site of (i.e. border of) the copper wiring and polyimide where the copper foil was removed between copper wirings or on the polyimide surface where the copper foil was removed between copper wirings was detected.

The polyimide film which was washed with Ni—Cr seed layer remover and in which copper was etched and removed was obtained by cutting out a sample with 10×10 cm in size from the rolled-up one-side copper foil laminated polyimide film, dipping the cut sample into ferric chloride solution (room temperature) as copper-etching solution for 20 min., washing with water after completely etching and removing the copper foil, then dipping into FLICKER-MH (made by Nihon Kagaku Sangyo Corporation) (temperature 30° C.) solution as Ni—Cr seed layer remover for 20 min., washing with water, further dipping into 5 wt % NaOH aqueous solution (temperature: 50° C.) for 1 min., and dipping into 3 vol % hydrochloric acid aqueous solution (room temperature: about 20° C.) for 30 sec.

### Example 2

### Process for Forming Circuit Through the Subtractive Method Using Carrier-Accompanied Copper Foil

Using the rolled-up one-side carrier-accompanied copper foil laminated polyimide film obtained from Example 1, a sample of 10.5 and 25 cm rectangular was cut out, and the carrier foil was stripped. After degreasing and acid-washing the copper foil laminated on the polyimide film, electrolytic copper-plating was conducted in a copper sulfate bath with the copper foil as a cathode electrode at a current density of 2 A/dm² at 25° C. for 20 min. so that the total thickness of copper became 9 μm. After laminating dry film-type negative-type photoresist (UFG-072 made by Asahi Chemical Industry) on the copper plating by a heat roll at 110° C., a site where circuit is intended to be formed was exposed, and unexposed resist was spray-developed with 1% sodium carbonate aqueous solution and removed at 30° C. for 20 sec., and the copper plating and the bare site of the copper foil was spray-etched with ferric chloride solution at 50° C. for 15 sec to form circuit part (wiring pattern with 40 μm in pitch). Subsequently, after stripping the resist by spray-treatment with 2% sodium hydroxide aqueous solution at 42° C. for 15 sec., the sample was dipped into FLICKER-MH made by Nihon Kagaku Sangyo as Ni—Cr seed layer remover at 45° C. for 5 min., then copper-wiring was tin-plated using Tinposit LT-34H made by SHIPLEY at 80° C. for 4 min.

The tin-plated copper wiring and the polyimide film surface where the copper foil was removed between copper wirings of the tin-plated copper-wiring polyimide film obtained was observed using a metallographic microscope (lens magnification: 500 times) in a similar way to Example 1.

Like Example 1, the polyimide surface where the copper foil was removed between copper wirings was clean, and no occurrence of anomalous metal deposition by tin-plating at the junction site of (i.e. border of) the copper wiring and polyimide where the copper foil was removed between copper wirings or on the polyimide film surface where the copper foil was removed between copper wirings was detected by visual inspection.

### Comparative Example 1

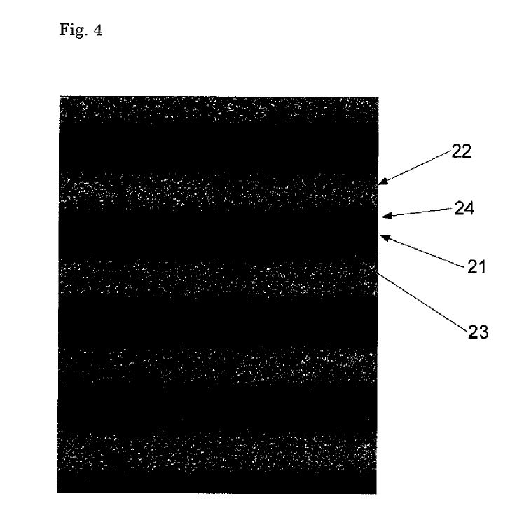

In Example 1, after copper-etching and removed, the washing step of the copper-wiring polyimide film with Ni—Cr seed layer remover was omitted. The copper-wiring polyimide film was thus produced. With respect to the tin-plated copper wiring and the polyimide film surface where the copper foil was removed between copper wirings of the tin-plated copper-wiring polyimide film obtained, an image was obtained by a metallographic microscope (measurement magnification: 500 times), which is shown in FIG. 4. From FIG. 4, occurrence of anomalous metal deposition by tin-plating at the junction site of (i.e. border of the copper wiring and polyimide where the copper foil was removed between copper wirings or on the polyimide film surface where the copper foil was removed between copper wirings was detected.

### Comparative Example 2

In Example 2, after copper-etching and removed, the washing step of the copper-etched and removed copper-wiring polyimide film with Ni—Cr seed layer remover was omitted. The copper-wiring polyimide film was thus produced. Tin-plating was carried out, and in the tin-plated copper-wiring polyimide film obtained, copper-wiring and the polyimide film surface where the copper foil was removed between copper wirings were observed using a metallographic microscope (lens magnification: 500 times).

Like Comparative Example 1, lots of occurrence of anomalous metal deposition by tin-plating at the junction site of (i.e. border of) the copper wiring and polyimide where the copper foil was removed between copper wirings were detected.

In FIG. 3 and FIG. 4, observation of the boundary part of the tin-plated copper wiring indicated by the reference 24 and the copper-removed polyimide film surface shows that in FIG. 3 the part is linear and the plating is accomplished normally; in FIG. 4 the linear part is hardly detected and it has irregular shapes, which shows that the plating has not been accomplished normally.

1. A process for producing a copper-wiring polyimide film, from a carrier-accompanied copper foil laminated polyimide film, by means of a subtractive method, the process comprising at least steps of:
1) stripping the carrier foil from the carrier-accompanied copper foil laminated polyimide film;
2) optionally plating copper on the copper foil;
3) forming an etching resist layer on an upper face of the copper foil;
4) exposing to light in a wiring pattern;
5) developing and removing the etching resist layer except a portion where the wiring pattern is intended to be formed;
6) removing by etching the copper foil except a portion where the wiring pattern is intended to be formed;
7) removing by stripping the etching resist layer; and
8) washing with an etching solution capable of removing at least one metal selected from Ni, Cr, Co, Zn, Sn and Mo or an alloy comprising at least one of these metals.

2. A process for producing a copper-wiring polyimide film, from a carrier-accompanied copper foil laminated polyimide film, by means of a semi-additive method, the process comprising at least steps of:
1) stripping the carrier foil from the carrier-accompanied copper foil laminated polyimide film;
2) optionally thinning by etching the copper foil;
3) forming a plating-resist layer on an upper face of the copper foil;
4) exposing to light in a wiring pattern;
5) developing and removing a portion of the plating-resist layer where the wiring pattern is intended to be formed;
6) plating copper on the bare part of the copper foil;
7) removing by stripping the plating-resist layer on the copper foil;
8) removing by flash-etching a portion of the copper foil where the plating-resist layer is removed to bare the polyimide; and
9) washing with an etching solution capable of removing at least one metal selected from Ni, Cr, Co, Zn, Sn and Mo or an alloy comprising at least one of these metals.

3. The process for producing a copper-wiring polyimide film according to claim 1, wherein in the carrier-accompanied copper foil laminated polyimide film, a surface of the carrier-accompanied copper foil is surface-treated with at least one metal selected from Ni, Cr, Co, Zn, Sn and Mo or an alloy comprising at least one of these metals; the surface being laminated to the polyimide film.

4. The process for producing a copper-wiring polyimide film according to claim 1, wherein said etching solution is capable of removing at least one metal selected from Ni, Cr, Co, Zn, Sn and Mo or an alloy comprising at least one of these metals at a faster rate than copper.

5. The process for producing a copper-wiring polyimide film according to claim 1, wherein the etching solution is an acidic etching solution.

6. The process for producing a copper-wiring polyimide film according to claim 1, wherein the etching solution is an etching agent for a Ni—Cr alloy.

7. The process for producing a copper-wiring polyimide film according to claim 3,
wherein in the polyimide film, a thermocompression-bondable polyimide layer is laminated on at least one side of a heat-resistant polyimide layer, and
wherein in the carrier-accompanied copper foil laminated polyimide film, the surface-treated face of the copper foil is laminated on the thermocompression-bondable polyimide layer of the polyimide film.

8. The process for producing a copper-wiring polyimide film according to claim 3,
wherein in the polyimide film, a thermocompression-bondable polyimide layer is laminated on at least one side of a heat-resistant polyimide layer, and
wherein in the carrier-accompanied copper foil laminated polyimide film, the surface-treated face of the copper foil is laminated by heat and pressure on the thermocompression-bondable polyimide layer of the polyimide film.

9. The process for producing a copper-wiring polyimide film according to claim 1, further comprising a step of plating a metal on at least a part of said copper-wiring after washing with said etching solution.

10. The copper-wiring polyimide film produced by the process according to claim 1.

11. The process for producing a copper-wiring polyimide film according to claim 2, wherein in the carrier-accompanied copper foil laminated polyimide film, a surface of the carrier-accompanied copper foil is surface-treated with at least one metal selected from Ni, Cr, Co, Zn, Sn and Mo or an alloy comprising at least one of these metals; the surface being laminated to the polyimide film.

12. The process for producing a copper-wiring polyimide film according to claim 2, wherein said etching solution is capable of removing at least one metal selected from Ni, Cr, Co, Zn, Sn and Mo or an alloy comprising at least one of these metals at a faster rate than copper.

13. The process for producing a copper-wiring polyimide film according to claim 2, wherein the etching solution is an acidic etching solution.

14. The process for producing a copper-wiring polyimide film according to claim 2, wherein the etching solution is an etching agent for a Ni—Cr alloy.

15. The process for producing a copper-wiring polyimide film according to claim 11,
wherein in the polyimide film, a thermocompression-bondable polyimide layer is laminated on at least one side of a heat-resistant polyimide layer, and
wherein in the carrier-accompanied copper foil laminated polyimide film, the surface-treated face of the copper foil is laminated on the thermocompression-bondable polyimide layer of the polyimide film.

16. The process for producing a copper-wiring polyimide film according to claim 11,
wherein in the polyimide film, a thermocompression-bondable polyimide layer is laminated on at least one side of a heat-resistant polyimide layer, and
wherein in the carrier-accompanied copper foil laminated polyimide film, the surface-treated face of the copper foil is laminated by heat and pressure on the thermocompression-bondable polyimide layer of the polyimide film.

17. The process for producing a copper-wiring polyimide film according to claim 2, further comprising a step of plating a metal on at least a part of said copper-wiring after washing with said etching solution.

18. The copper-wiring polyimide film produced by the process according to claim 2.
